(19) United States
(12) Patent Application Publication
(10) Pub. No.: US 2018/0277787 A1
(43) Pub. Date: Sep. 27, 2018

(54) THERMALLY STABLE SILVER NANOWIRE TRANSPARENT ELECTRODE

(71) Applicant: The Regents of the University of California, Oakland, CA (US)

(72) Inventors: Qibing Pei, Los Angeles, CA (US); Dustin Chen, Los Angeles, CA (US); Jiajie Liang, Los Angeles, CA (US)

(73) Assignee: The Regents of the University of California, Oakland, CA (US)

(21) Appl. No.: 15/764,676

(22) PCT Filed: Oct. 3, 2016
(86) PCT No.: PCT/US2016/055197

§ 371 Date: Mar. 29, 2018

Related U.S. Application Data
(60) Provisional application No. 62/235,897, filed on Oct. 1, 2015.

(51) Int. Cl. H01L 51/52; H01L 51/50; H01L 51/56; H01L 51/00

(52) U.S. Cl. CPC H01L 51/5206; H01L 51/5268; H01L 51/5246; H01L 51/502; H01L 51/5253; H01L 27/323; H01L 51/0021; H01L 51/003; H01L 51/0035; H01L 51/004; H01L 2251/301; H01L 51/56

(57) ABSTRACT

A transparent conductive film having a first surface and a second surface, the second surface opposite the first surface; and at least one thermally stable substrate attached to the second surface. The transparent conductive film includes a plurality of thermally stable nanowires embedded within at least one polymer binder, the thermally stable nanowires include metal nanowires, the first surface includes a conductive surface of a plurality of the nanowires, the transparent conductive film has a sheet resistance that degrades by no more than 5% when heated to 300° C. for 1 hour, and the transparent conductive film has a transmittance at a wavelength of 550 nm that decreases by no more than 5% when heated to 300° C. for 1 hour. In one example, silver nanowires are made thermally stable using a thin layer of ZnO deposited using atomic layer deposition.

### CROSS REFERENCE TO RELATED APPLICATIONS

This application claims priority under 35 U.S.C. § 119(e) of co-pending and commonly-assigned U.S. Provisional Patent Application Ser. No. 62/235,897, entitled “THERMALLY STABLE SILVER NANOWIRE TRANSPARENT ELECTRODE,” filed on Oct. 1, 2015, by Qibing Pei, Dustin Chen, and Jiajie Liang, attorney's docket number 30435.295-US-P1, which application is incorporated by reference herein.

This application is further related to the following co-pending and commonly-assigned applications:

U.S. Utility patent application Ser. No. 13/783,284, filed on Mar. 2, 2013, by Qibing Pei and Zhibin Yu, entitled “NANOWIRE-POLYMER COMPOSITE ELECTRODES”, Attorney's Docket No. 30435.293-US-C1 (UC Ref No. 2011-133), which application is a continuation of PCT application No. US2011/053107 filed on Sep. 23, 2011, which PCT application claims priority to and the benefit under 35 U.S.C. § 119(e) of U.S. Provisional Application Ser. No. 61/386,454 filed on Sep. 24, 2010; and

U.S. Utility patent application Ser. No. 14/600,194, filed on Jan. 20, 2015, by Qibing Pei, entitled “HIGH EFFICIENCY ORGANIC LIGHT EMITTING DEVICES”, Attorney's Docket No. 30435.294-US-C1 (UC Ref. No. 2013-001); which application is a continuation of PCT application No. US2013/051349 filed on Jul. 19, 2011, which PCT application claims priority to and the benefit under 35 U.S.C. § 119(e) of U.S. Provisional Application Ser. No. 61/674,197 filed on Jul. 20, 2012;

all of which applications are incorporated by reference herein.

### STATEMENT REGARDING FEDERALLY SPONSORED RESEARCH AND DEVELOPMENT

This invention was made with Government support under 1414415, awarded by the National Science Foundation. The Government has certain rights in the invention.

### BACKGROUND OF THE INVENTION

### 1. Field of the Invention

This invention relates to a method for fabricating transparent electrodes for organic devices.

### 2. Description of the Related Art

(Note: This application references a number of different publications as indicated throughout the specification by one or more reference numbers in superscripts [x]. A list of these different publications ordered according to these reference numbers can be found below in the section entitled “References.” Each of these publications is incorporated by reference herein.)

In view of the rapid development of next generation wearable electronics, the search for high performing and flexible or stretchable transparent conductive electrodes (TCEs) is the subject of much activity. The current industry standard for TCEs is indium tin oxide (ITO), which has been ubiquitous for most practical thin-film transparent electrode applications over the course of the past several decades.^{[2]} However, due to high materials and fabrication cost and limited mechanical compliancy, a push to find a replacement for ITO has arisen over recent years. Metal-based nanowires, such as silver nanowires (AgNW) networks, have leaped to the forefront of potential candidates due to their desirable electrical, mechanical, and optical properties, in addition to being solution processed, allowing for high speed, low cost, roll-to-roll processing.

Despite the advantages afforded to TCEs manufactured from AgNW networks unrealized with ITO/glass electrodes, the AgNW based TCE electrodes are still lacking in other areas, notably their rough surface topology, poor thermal stability, and lack of barrier properties of the TCE.^{[13]} Several attempts at ameliorating these issues have been reported, though a comprehensive solution to the aforementioned problems has not yet surfaced. Embedding the AgNW layer within the top layer of a polymer has been shown to drastically reduce the surface roughness,^{[13-18]} which can prevent short circuits that can lead to device failure. With this technique, a glass substrate is typically used to provide a smooth release for the AgNW infused with polymer, yielding surface roughnesses below 2 nm.^{[14]} To improve thermal stability, polymers with a higher glass transition temperature (T_{g}) such as polyimide, or reinforced hybrid polymers have been used.^{[13,15-17,19]} As an example, a previous work by two of the inventors used AgNWs inlaid in the surface of a heat-resistant acrylate matrix to be used as a thin film heater, though the device was only tested at a maximum temperature of 230° C. for time scales under 5 minutes.^{[17]}

However, TCEs with thermally stable polymer matrices do not account for the thermal stability of the AgNW themselves, which have been shown to exhibit an increase in sheet resistance at 180° C. when the nanowires are freestanding, and often at even lower temperatures when embedded in a polymer matrix.^{[20]} This increase of electrical resistivity is due to nanoscale size effects, causing nanowires (NWs) to melt at a significantly lower temperature than the melting temperature of bulk silver, manifesting in the AgNWs breaking and re-forming as metal droplets.^{[21]}

A sandwich layer of zinc oxide (ZnO)/AgNW/ZnO has been shown to increase the thermal stability of the silver nanowires,^{[19,22,23]} but the continuous layer of ZnO over the AgNW film prohibits the infiltration of a polymer precursor to form a percolation network, leading to a high surface roughness which can cause shorts and device failure.

Chen et al. used stamp-transferred graphene on AgNW to allow graphene to dissipate heat in order to protect the AgNWs, but were only able to main stability at 200° C. for three hours, in addition to not fabricating freestanding films.^{[21]} The use of neutral-pH poly(3,4-ethylenedioxythiophene):poly(styrenesulfonate) (PEDOT:PSS) was reported to improve thermal stability of the AgNW electrode, but could only withstand 20 minutes annealing at 210° C. due to the degradation of PEDOT:PSS at high temperatures.^{[24]} Finally, the plastic substrates generally used for the fabrication of AgNW based TCEs have poor water vapor transmission rates (WVTR), leading to rapid degradation of optoelectronic devices requiring inert atmospheres. Barrier films are generally required to remedy this issue, which adds further material, time, and labor costs to the fabrication process.

### SUMMARY OF THE INVENTION

The present invention discloses a transparent electrode structure comprising nanowires and having surprisingly and unexpectedly improved thermal performance while maintaining desirable transparency and conductivity and surface smoothness. For example, in depth investigation performed on ALD deposited ZnO on AgNWs has found surprising and unexpected performance improvement in thermal and atmospheric corrosion stability. For example, one or more embodiments of the present invention surprisingly and unexpectedly disclose a flexible transparent conductive electrode with extremely smooth topography capable of withstanding thermal processing at 300° C. for at least 6 hours with little change in sheet resistance and optical clarity.

In one embodiment, the ZnO coated nanowire networks were embedded within the surface of a polyimide (PI) matrix, and the <2 nanometer (nm) roughness freestanding electrode was used to fabricate a white Polymer Light Emitting Diode (PLED). PLEDs obtained using the ZnO—AgNW—PI substrate exhibited comparable performance to ITO/glass based devices, verifying its efficacy for use in optoelectronic devices requiring high processing temperatures.

However, the transparent electrode of the present invention is embodied in many ways, including, but not limited to the following.

1. In one embodiment, the electrode structure comprises a transparent conductive film having a first surface and a second surface, the second surface opposite the first surface; and at least one first thermally stable material attached to the second surface, wherein the transparent conductive film includes a plurality of thermally stable nanowires and at least one polymer binder. The thermally stable nanowires include metal nanowires and the first surface includes the conductive surfaces of a plurality of the nanowires. In this way, a conductive surface of the nanowires is exposed.

2. In one embodiment, the metal nanowires consist essentially of metal, such as, but not limited to, silver, copper, aluminum, gold, nickel, stainless steel, and alloys thereof.

3. In one or more embodiments of any of the preceding embodiments 1-2, the transparent conductive film has a sheet resistance that degrades by no more than 5% when heated to 250° C. for 1 hour, and the transparent conductive film has a transmittance at a wavelength of 550 nm that decreases by no more than 5% when heated to 250° C. for 1 hour.

4. In one or more embodiments of any of the preceding embodiments 1-3, the first surface has a surface roughness of 2 nm or less.

5. In one or more embodiments of any of the preceding embodiments 1-4, the thermally stable nanowires are disposed such that the first surface has a sheet resistance of 50 Ohms per square or less.

6. In one or more embodiments of any of the preceding embodiments 1-5, the thermally stable nanowires comprise the metal nanowires conformally coated with an overcoat comprising or consisting essentially of thermally stable material.

7. In one or more embodiments of any of the preceding embodiments 1-6, the thermally stable nanowires each comprise one of the metal nanowires and at least one overcoat protective layer deposited directly on the one of the metal nanowires by atomic layer deposition (ALD), the overcoat protective layer deposited with a thickness of 25 nm or less (e.g., in a range of 1.5 nm-25 nm).

8. In one or more embodiments of any of the preceding embodiments 1-7, the at least one overcoat protective layer comprises or consists essentially of at least one oxide selected from an oxide of zinc, an oxide of aluminum, an oxide of hafnium, an oxide of zirconium, and an oxide titanium.

9. In one or more embodiments of any of the preceding embodiments 1-8, the at least one overcoat protective layer comprises or consists essentially of at least one nitride selected from a nitride of titanium, a nitride of tantalum, a nitride of hafnium, and a nitride of tungsten.

10. In one or more embodiments of any of the preceding embodiments 1-9, the at least one overcoat protective layer on the nanowires is formed from self-assembled monolayers.

11. In one or more embodiments of any of the preceding embodiments 1-10, the at least one thermally stable material comprises or consists essentially of a sheet of glass attached to the second surface of the transparent conductive film.

12. In one or more embodiments of any of the preceding embodiments 1-11, the sheet of glass comprises or consists essentially of a thin and flexible sheet of glass.

13. In one or more embodiments of any of the preceding embodiments 1-12, the thermally stable material (e.g., the sheet of glass) is pre-coated with a layer of a difunctional compound having on one end a functional group that enables bonding to a surface of the at least one thermally stable material, and on the other end a functional group that enables bonding to the polymer binder.

14. Examples of the difunctional compound include, but are not limited to, 3-(Monochlorosilyl)propyl methacrylate, 3-(Dichlorosilyl)propyl methacrylate, 3-(Trichlorosilyl)propyl methacrylate, 3-(Monoalkoxysilyl)propyl methacrylate, 3-(Dialkoxysilyl)propyl methacrylate, 3-(Trialkoxysilyl)propyl methacrylate, and polymers containing the same mono-/di-/tri-chloro silane and mono-/di-/tri-alkoxy silane but with styrl, acrylate, or other vinyl/olefin groups substituted for methacrylate.

15. In one or more embodiments of any of the preceding embodiments 1-14, the at least one polymer binder embeds the nanowires and comprises or consists essentially of at least one polymer selected from polyimide, polyacrylate, polyurethane, silicone, epoxy, polybenzoxazole, polyhedral oligomeric silsequioxane, polydimethylsiloxane, and mixtures thereof.

16. In one or more embodiments of any of the preceding embodiments 1-15, the at least one polymer binder includes a layer of polyacrylate chemically bonded to the thermally stable material comprising or consisting essentially of a sheet of glass.

17. In one or more embodiments of any of the preceding embodiments 1-16, the at least one polymer binder contains light scattering particles.

18. In one or more embodiments of any of the preceding embodiments 1-17, the at least one polymer binder contains high refractive index nanoparticles with average diameter less than 10 nm.

19. In one or more embodiments of any of the preceding embodiments 1-18, the least one polymer binder includes a layer of polyimide.

One or more embodiments of the present invention further disclose a high efficiency light emitting device, comprising the transparent conductive film of any of the preceding embodiments, wherein the transparent conductive film is a first electrode; at least a charge injection layer electrically coupled to the transparent conductive film; an emissive layer (e.g., an organic luminescent compound, luminescent quantum dots); and a second electrode electrically coupled to the emissive layer, wherein the emissive layer is between the charge injection layer and the second electrode.

One or more embodiments of the present invention further disclose a lighting panel comprising at least a light-emitting diode formed on the transparent conductive film of any of the preceding embodiments; a solid barrier structure; at least one seal for adhering said barrier structure to the thermally stable material, wherein the seal, the barrier structure, and the thermally stable material, in combination, define an enclosed space, and the light emitting diode is within the enclosed space.

Examples of materials from which the barrier structure is made include glass, ceramic, metal, metal oxide, polymer, or a combination these materials.

In one or more embodiments, the seal comprises or consists essentially of cured epoxy, polydimethylsiloxane, or glass frit.

One or more embodiments of the present invention further disclose a white light emitting OLED, comprising a light emitting diode emitting white light and formed on the electrode structure of any of the preceding embodiments, the thermally stable material comprising or consisting essentially of a glass mount; and a glass cover on the light emitting diode.

In one or more embodiments, the transparent conductive film has a smooth conductive surface (e.g., peeled from a glass substrate), a thermal stability, a sheet resistance, and a transmittance and scattering coefficient for the white light, and he light emitting diode has a device structure, such that the OLED has a current efficiency of at least 99 cd/A and a power efficiency of at least 100 lm/W.

In one or more embodiments, the transparent conductive film has a smooth conductive surface, a thermal stability, a sheet resistance, and a transmittance and scattering coefficient for the white light, such that the OLED has a power efficiency that is at least 1.8 times larger than a power efficiency of an OLED comprising the light emitting diode formed on an ITO electrode.

In one or more embodiments, the transparent conductive film has a smooth conductive surface, a thermal stability, a sheet resistance, and a transmittance and scattering coefficient for white light, such that the OLED has a current efficiency that is at least 1.8 times larger than a power efficiency of an OLED comprising the light emitting diode formed on an ITO electrode.

One or more embodiments of the present invention further disclose a method of fabricating a transparent conductive film of any of the preceding embodiments on a substrate, comprising applying at least one first coating onto a release substrate, wherein the at least one first coating comprises metallic or metal nanowires, carbon nanotubes, graphene, or mixtures thereof; applying at least one polymer precursor on the first coating; overlaying at least one layer of a thermally stable material on the polymer precursor; curing or drying the at least one polymer precursor; and removing the first coating, the polymer precursor, and the thermally stable material from the release substrate to transfer the silver nanowire network onto the thermally stable material.

### BRIEF DESCRIPTION OF THE DRAWINGS

Referring now to the drawings in which like reference numbers represent corresponding parts throughout:

FIG. 1 is a flowchart illustrating a method of fabricating a device according to one or more embodiments of the present invention.

FIGS. 2A-2D are cross-sectional schematics illustrating a method of fabricating a device according to one or more embodiments of the present invention.

FIGS. 3A-3D illustrate characterization of AgNW films, wherein FIG. 3A shows Raman spectra of the GO-coated glass release substrate before (top) and after (bottom) PI transfer of ZnO—AgNW film, FIG. 3B shows AgNW bar coated on a glass slide after a 150° C. anneal for 30 minutes (min), FIG. 3C shows AgNW coated on a glass substrate after a 200° C. anneal for 30 minutes, and FIG. 3D shows AgNW coated on a glass substrate after a 250° C. anneal for 30 minutes.

FIGS. 4A-4F are electron microscopic images of AgNW with ZnO deposited with ALD under different annealing conditions according to one or more embodiments of the present invention, wherein FIG. 4A is a Transmission Electron Microscope (TEM) image of pristine (top), and ZnO coated AgNW (bottom), FIG. 4B is a Scanning Electron Microscope (SEM) image of ZnO-coated AgNW (ZnO—AgNW) on a glass substrate without annealing, FIG. 4C is an SEM image illustrating positive and negative curvatures, FIG. 4D is an SEM image of ZnO—AgNW having a 1.5 nm thickness of ZnO after a 250° C. anneal for 30 minutes, FIG. 4E is an SEM image of ZnO—AgNW having a 1.5 nm thickness of ZnO after a 300° C. anneal for 30 minutes, and FIG. 4F is an SEM image of ZnO—AgNW having a 4.5 nm thickness of ZnO after a 300° C. anneal for 30 min.

FIGS. 5A-5C illustrate optical and electrical characterization of ZnO-coated AgNW films according to one or more embodiments of the present invention, wherein FIG. 5A plots normalized sheet resistance R/Rₒ of ZnO-coated AgNW vs temperature, with the normalized sheet resistance for ZnO—AgNW and pristine AgNW plotted on a logarithmic scale in the inset, FIG. 5B shows an ultraviolet-visible (UV-vis) spectrum of annealed and non-annealed ZnO-coated AgNW films and pristine AgNW films wherein AgNW (A) denotes annealed samples, and FIG. 5C plots the percolative figure of merit (FOM) and percolation exponent as a function of annealing temperature for both ZnO-coated AgNW films and pristine AgNW films.

FIG. 6A shows a fabrication process for a freestanding ZnO—AgNW—PI film according to one or more embodiments of the present invention, and FIGS. 6B-6E illustrate characterization of the ZnO—AgNW—PI freestanding electrode fabricated according to FIG. 6A, wherein FIG. 6B is an optical image of a ZnO—AgNW—PI composite electrode, FIG. 6C is an atomic force microscope (AFM) image of an embedded ZnO—AgNW—PI substrate, FIG. 6D plots normalized sheet resistance R/Rₒ of the ZnO—AgNW—PI heated at 300° C., and two reference electrodes annealed at 250° C., as a function of hours annealed, and FIG. 6E is a UV-vis spectra (plotting % transparency as a function of wavelength) of a ZnO—AgNW—PI film annealed at 300° C. for 1 hour and an AgNW—PI film annealed at 250° C. for one hour.

FIGS. 7A-7E compare the structure and electrical performance of pristine AgNW and ZnO—AgNW according to one or more embodiments of the present invention, wherein FIG. 7A is a TEM image of pristine AgNW, FIG. 7B is a TEM of ZnO—AgNW, FIG. 7C is an SEM image of pristine AgNW after annealing at 250° C., FIG. 7D is an SEM image of ZnO—AgNW after annealing at 300° C., and FIG. 7E compares the sheet resistance of an AgNW—PI film and a ZnO—AgNW—PI film.

FIGS. 8A-8B illustrate performance of a white PLED on the ZnO—AgNW—PI substrate according to one or more embodiments of the present invention, wherein FIG. 8A plots current density (milliamps (mA) per centimeter square (cm²) as a function of voltage for various substrates annealed at 250° C. and 300° C. (the ITO is annealed at 300° C. and the data for a PLED based on ZnO—AgNW-Acrylate heated at 300° C. is shown in the inset on a linear scale), and FIG. 8B plots luminance (candela per square meter, cd/m²) as a function of voltage for the PLED devices with various substrates annealed at 250° C. and 300° C. (the ITO is annealed at 300° C.).

FIGS. 9A-9D illustrate characterization of the light emitting device fabricated according to the method illustrated in FIG. 10A-10F, as compared to performance of the light emitting device of FIG. 10F comprising an ITO electrode instead of the transparent electrode of FIG. 10D, wherein FIG. 9A plots current density as a function of voltage, FIG. 9B plots power efficiency as a function of luminance, FIG. 9C plots current efficiency as a function of luminance, and FIG. 9D is a table tabulating the current efficiency, power efficiency, and luminance at 5 volts (V), for the device having the ITO electrode and the device having the structure illustrated in FIG. 10F.

FIGS. 10A-10F illustrate a method of fabricating a device according to one or more embodiments of the present invention, and FIG. 10G is a photograph of the fabricated device during operation.

### DETAILED DESCRIPTION OF THE INVENTION

In the following description of the preferred embodiment, reference is made to the accompanying drawings which form a part hereof, and in which is shown by way of illustration a specific embodiment in which the invention may be practiced. It is to be understood that other embodiments may be utilized and structural changes may be made without departing from the scope of the present invention.

### Technical Description

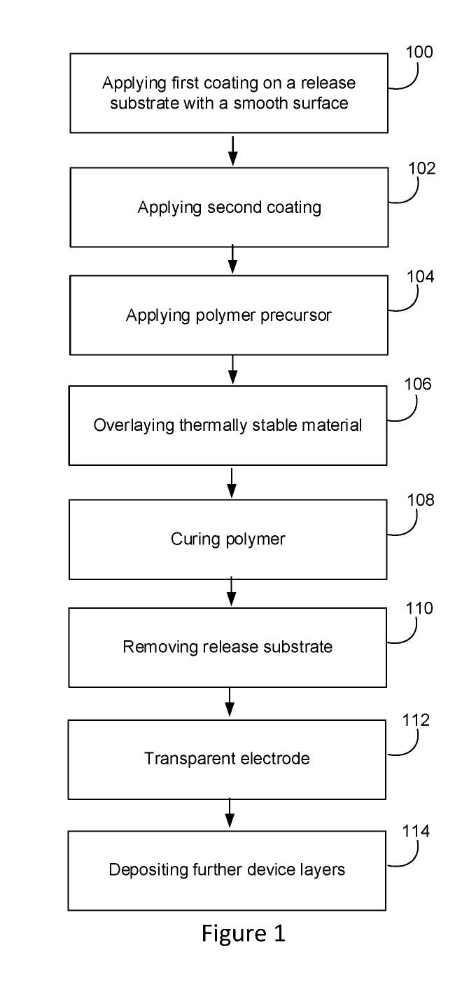

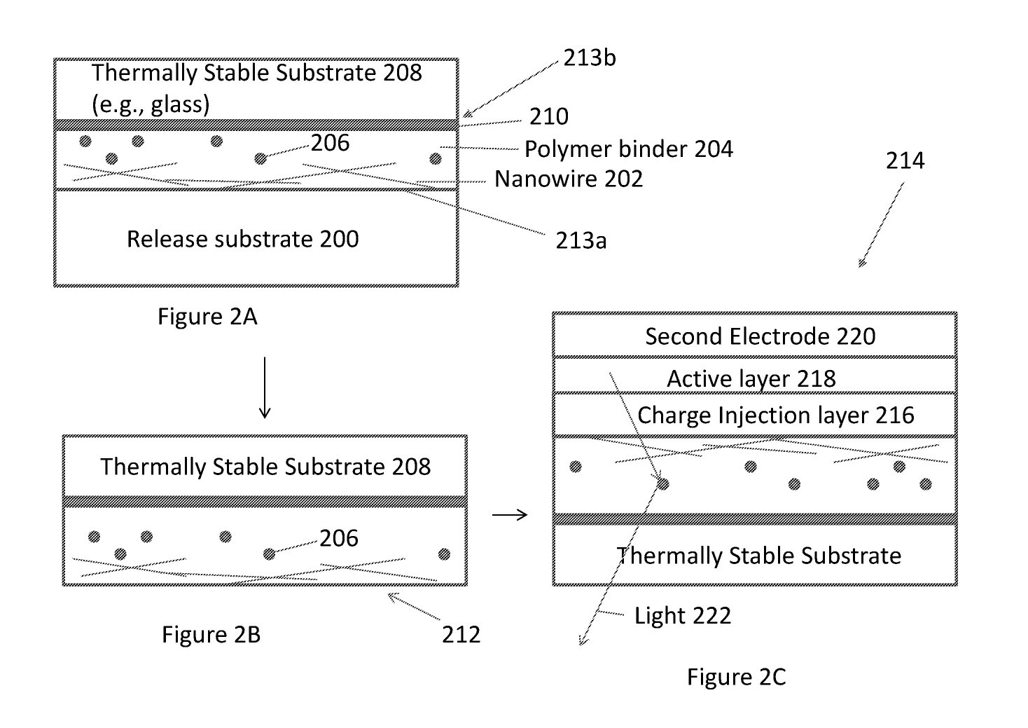

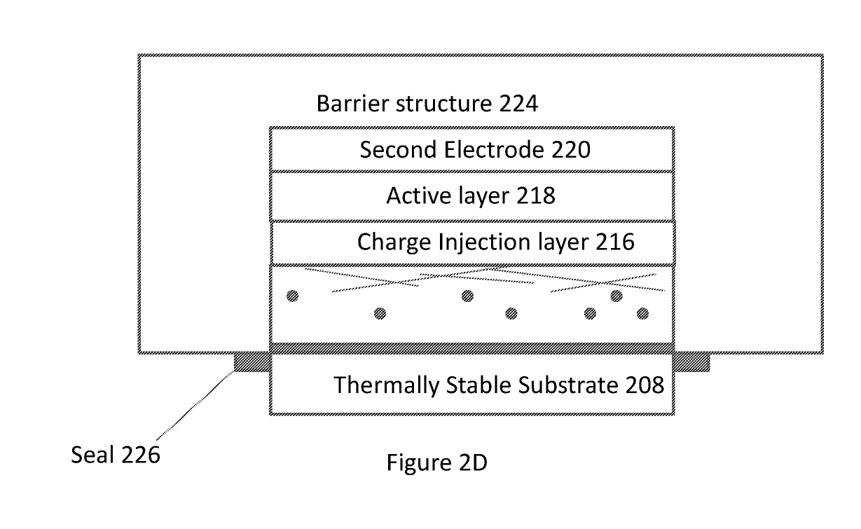

FIGS. 1 and 2A-D illustrate a method of fabricating a device structure comprising a transparent conductive electrode, according to one or more embodiments of the invention. The method can comprise the following steps.

Block 100 represents applying at least one first coating (first coating mixture or first coated layer) onto a release substrate 200. In one or more embodiments, the at least one first coating comprises metallic nanowires 202, nanoparticles, carbon nanotubes, graphene, or mixtures thereof. Examples of metallic nanowires include, but are not limited to, metal nanowires or nanowires consisting essentially of metal. Examples of the metal include, but are not limited to, silver, copper, aluminum, gold, nickel, stainless steel, and alloys thereof.

In one or more embodiments, the nanowires, nanotubes, or nanoparticles have a diameter in a range of 1-100 nanometers (nm).

In one or more embodiments, the release substrate is rigid glass, flexible glass, and/or a flexible plastic film, such as polyethylene terephthalate (PET) or polyimide (PI) (e.g., with a smooth surface).

In one or more embodiments, a release agent is applied to the release substrate prior to coating the first coating. In one or more examples, the release agent is a carbon based material including carbon nanotubes and graphene oxide.

Block 102 represents optionally applying at least one second coating onto the at least one first coating, to form a protective overlayer.

In one or more examples, the second coating comprises at least one overcoat protective layer deposited on the (e.g., silver) nanowire 202 network by ALD with a thickness of 25 nm or less, such that the thermally stable nanowires each comprise one of the metal nanowires and the at least one overcoat protective layer deposited on the one of the metal nanowires. Thickness of the overcoat layer can be in the range of 1.5 nm-25 nm, for example.

In one or more examples, the at least one overcoat protective layer is selected from oxides of zinc, aluminum, hafnium, zirconium, and titanium. In one or more further examples, the at least one overcoat protective layer is selected from nitrides of titanium, tantalum, hafnium, and tungsten. In yet a further embodiment, the at least one overcoat protective layer comprises a ceramic.

In one or more further embodiments, the least one overcoat protective layer on the (e.g., silver) nanowire 202 network is formed by/from/as self-assembled monolayers.

In one or more embodiments, the overcoat on the nanowires 202 forms a thermally stable nanowire comprising a metal core and a shell, wherein the metal core comprises or consists essentially of metal such, as but not limited to, silver, copper, aluminum, gold, nickel, stainless steel, and alloys thereof (as described above) and the shell comprises or consists essentially of the overcoat protective layer materials described in Block 102 (e.g., at least one oxide selected from an zinc, aluminum, hafnium, zirconium, and titanium or at least one nitride selected from a nitride of titanium, tantalum, hafnium, and tungsten).

Block 104 represents applying at least one liquid monomer or polymer precursor/binder 204 on the first or second coating, e.g., to embed the network of (e.g., silver) nanowires 202.

In one or more examples, the polymer precursor comprises (e.g., a layer of) polyimide, polyacrylate, polyurethane, silicone, epoxy, polybenzoxazole, polyhedral oligomeric silsequioxane, polydimethylsiloxane, or mixtures thereof. In one or more further examples, the at least one polymer binder includes, but is not limited to, a layer of polyacrylate chemically bonded to a thermally stable glass substrate 208.

In yet another example, the liquid monomer comprises acrylate.

In yet a further embodiment, the at least one polymer binder 204 or liquid monomer contains light scattering particles 206, such as, but not limited to, high refractive index nanoparticles with average diameter larger than 10 nm. However, in another example, the at least one polymer binder 204 or liquid monomer contains high refractive index nanoparticles with average diameter less than 10 nm to increase the overall refractive index of the polymer binder layer.

In one or more examples, the binder/precursor has a thickness of 40 micrometers.

Block 106 represents overlaying at least one layer of a thermally stable material/substrate 208 on the polymer binder/precursor 204. Examples of the at least one layer of thermally stable material include, but are not limited to, a sheet of glass, rigid glass, flexible glass (e.g., a sheet of Willow® glass), or plastic (e.g., PI or PET). \

In one or more embodiments, the sheet of glass is thin (e.g., has a thickness in a range of 20-200 micrometers) and/or the sheet of glass is flexible.

In one or more embodiments, the thermally stable material (e.g., comprising rigid glass or flexible glass) is pre-coated with a layer 210 (e.g., a monolayer) of a difunctional compound having on one end a functional group that enables bonding to the surface (e.g., the glass surface) of the thermally stable material, and on the other end a functional group that enables bonding to the curable polymer precursor 204. Examples of the difunctional compound include, but are not limited to, 3-(Monochlorosilyl)propyl methacrylate, 3-(Dichlorosilyl)propyl methacrylate, 3-(Trichlorosilyl)propyl methacrylate, 3-(Monoalkoxysilyl)propyl methacrylate, 3-(Dialkoxysilyl)propyl methacrylate, 3-(Trialkoxysilyl)propyl methacrylate, and/or polymers containing the same mono-/di-/tri-chloro silane and mono-/di-/tri-alkoxy silane but with styrl, acrylate, or other vinyl/olefin groups substituted for methacrylate.

Block 108 represents curing or drying the at least one polymer precursor 204.

Block 110 represents removing the aforementioned layers (including first coating, second coating (if applicable), polymer binder 204, and thermally stable material 208) from the release substrate 200 to transfer the (e.g., silver) nanowire 202 network onto the thermally stable substrate 208, as illustrated in FIG. 2B. In one example, the conductive surface 213a is a surface peeled from the substrate 200 comprising/consisting of a glass substrate.

Block 112 and FIG. 2B represents the result of steps 100-108, a transparent conductive film 212 having a first surface 213a and a second surface 213b, the second surface 213b opposite the first surface 213a; and at least one thermally stable material 208 (e.g., submount or substrate) attached to the second surface 213b. The transparent conductive film includes a plurality of thermally stable nanowires 202 and a matrix (comprising at least one polymer binder 204), the thermally stable nanowires includes metal nanowires (e.g., a network of metal (e.g., silver) nanowires), and the first surface includes conductive surfaces of a plurality of the nanowires. Thus, one or more of the nanowires can be in a surface layer of the binder 204 and surface 213a can be a conductive surface.

In one or more embodiments, the sheet resistance of the transparent conductive film 212 degrades by no more than 5% when heated to 300° C. for at least 1 hour and/or the transmittance of the transparent conductive film 212 at a wavelength of 550 nm decreases by no more than 5% when heated to 300° C. for at least 1 hour.

In one or more embodiments, the first surface 213a has a surface roughness of 2 nanometers (nm) or less and/or a sheet resistance of 50 Ohms per square or less. In one or more embodiments, the metal nanowires are conformally coated with a thermally stable material (e.g., the overcoat). In one or more embodiments, the first surface 213a has a surface roughness Ra of 2 nanometers (nm) or less, where Ra is defined as the arithmetic average of the absolute values.

In one or more embodiments, the thermally stable material(s) (material 208 deposited in Block 106 and/or overcoat deposited in Block 102) are one or more materials retraining sufficient conductivity, sufficient resistance to atmospheric corrosion (which subsequently plays a role in the optical properties of the nanowire network), and structural properties (sufficient resistance to atomic diffusion or melting) when the material is heated to at least 250° C. for at least 1 hour, and/or the thermally stable material(s) (material 208 deposited in Block 106 and/or overcoat deposited in Block 102) are one or more materials whose conductivity, resistance to atmospheric corrosion, and structural properties do not significantly degrade when the material is heated to at least 250° C. for at least 1 hour, such that:
the sheet resistance of the transparent conductive film 212 degrades by no more than 5% when the transparent conductive film is heated to at least 250° C. for at least 1 hour, and/or
the transmittance of the transparent conductive film 212 at a wavelength of 550 nm decreases by no more than 5% when the transparent conductive film is heated to at least 250° C. for at least 1 hour, and/or
the transmittance of the transparent conductive film at the wavelength of 550 nm is at least 80% after heating the transparent conductive film to at least 250° C. for at least 1 hour, and/or
the first surface 213a has a surface roughness of 2 nanometers (nm) or less after heating the transparent conductive film to at least 250° C. for at least 1 hour, and/or
the first surface 213a has a sheet resistance of 50 Ohms per square or less after heating the transparent conductive film to at least 250° C. for at least 1 hour.

In one or more further embodiments, the polymer binder 204 is a material whose material properties (including optical transparency and mechanical properties) are retained or are not significantly degraded upon heating to at least at least 250° C. for at least 1 hour, such that:
the sheet resistance of the transparent conductive film 212 degrades by no more than 5% when the transparent conductive film is heated to at least 250° C. for at least 1 hour, and/or
the transmittance of the transparent conductive film 212 at a wavelength of 550 nm decreases by no more than 5% when the transparent conductive film is heated to at least 250° C. for at least 1 hour, and/or
the transmittance of the transparent conductive film at the wavelength of 550 nm is at least 80% after heating the transparent conductive film to at least 250° C. for at least 1 hour, and/or
the first surface 213a has a surface roughness of 2 nanometers (nm) or less after heating the transparent conductive film to at least 250° C. for at least 1 hour, and/or
the first surface 213a has a sheet resistance of 50 Ohms per square or less after heating the transparent conductive film to at least 250° C. for at least 1 hour.

In one or more embodiments, the polymer binder and the thermally stable material(s) are robust or sufficiently robust to achieve the transparent conductive film having the above described performance.

Block 114 represents depositing (e.g., spin coating or evaporating) further device layers (e.g., for an OLED) on the transparent conductive film, to form a device 214 as illustrated in FIG. 2C.

FIG. 2C illustrates a high efficiency light emitting device 214 comprising/formed on the transparent conductive film 212, according to one or more embodiments, and wherein the transparent conductive film is a first electrode. The light emitting device comprises at least a first charge injection layer 216 electrically coupled to the transparent conductive film 212; an emissive layer 218 on the charge injection layer 216; and a second electrode (including second charge injection layer) 220 electrically coupled to the emissive layer 218, wherein the emissive layer 218 is an active layer that emits electroluminescence/light 222 in response to an electrical bias applied across the electrodes 212, 220.

In one or more embodiments, the emissive layer comprises an organic luminescent compound or luminescent quantum dots.

In one or more embodiments, the device comprising an OLED 214 on the transparent conductive film 212 on the glass substrate 208 has an external quantum efficiency (EQE) increased by a factor of at least two as compared to the device comprising the OLED on an ITO electrode on a glass substrate (the OLED on an ITO electrode on a glass substrate typically has an external quantum efficiency of 20%). Thus, one or more embodiments of the invention increase extraction of light 222 emitted by the emissive layer 218 of the OLED through the electrode and substrate (comprising the transparent conductive film 212 on glass substrate 208) by a factor of at least two as compared to extraction of light from the emissive layer 218 through ITO on the glass substrate.

In one or more embodiments, the device 214 is an OLED comprising a light emitting diode structure and the transparent conductive film 212 having a smooth conductive surface, a thermal stability, a sheet resistance, and a transmittance and scattering coefficient for the white light such that the OLED has a current efficiency of at least 99 cd/A and a power efficiency of at least 100 lm/W, a power efficiency that is at least 1.8 times larger than a power efficiency of an OLED comprising the light emitting diode formed on an ITO electrode, and/or a current efficiency that is at least 1.8 times larger than a power efficiency of an OLED comprising the light emitting diode formed on an ITO electrode.

FIG. 2D illustrates an example of a lighting panel comprising at least a light-emitting diode formed on the transparent conductive film, a solid barrier structure 224; at least one seal 226 for adhering said barrier structure 224 to the thermally stable substrate 208 of the transparent conductive film 212, wherein the combination of the seal 226, the barrier structure 224, and the thermally stable substrate 208 defines an enclosed space, and the light emitting diode is within the enclosed space. In one or more examples, the barrier structure 224 is made from glass, ceramic, metal, metal oxide, polymer or a combination thereof. In one or more examples, the seal 226 comprises cured epoxy, polydimethylsiloxane, or glass frit. In one or more examples, the barrier structure 224 and the thermally stable substrate 208 (e.g., glass) are transparent and provide a good (e.g., hermetic) barrier to O₂ and/or moisture, preventing O₂ and/or moisture from reaching and degrading the OLED.

Examples Comprising a Transparent Conductive Electrode with Overcoat Layer

In this section, the present disclosure reports on the use of a low temperature ALD process to coat a conformal, thin layer of ZnO around individual nanowires to enhance the thermal stability of AgNWs (the ZnO layer prevents the melting and coalescence of AgNWs observed at annealing temperatures above 180° C.) while maintaining a porous structure or porous network structure. Thermally stable and colorless polyimide (PI) was chosen as the polymer matrix to embed the coated AgNWs. When the transparent, colorless PI was infiltrated between the nanowires, the resulting freestanding films were able to withstand annealing at 300° C. for over six hours, showing little to no degradation in electrical or optical properties.

The resulting composite electrode successfully resolves the issue of thermal stability for both the AgNWs and the polymer matrix. The composite sheets show high thermal stability and mechanical flexibility, and outperform ITO/polyethylene terephthalate (PET), a common transparent flexible electrode, in visual transparency, surface conductivity, and surface smoothness. The efficacy of the new ZnO—AgNW—PI TCE was demonstrated by solution-processing PLEDs.

1. Example Fabrication

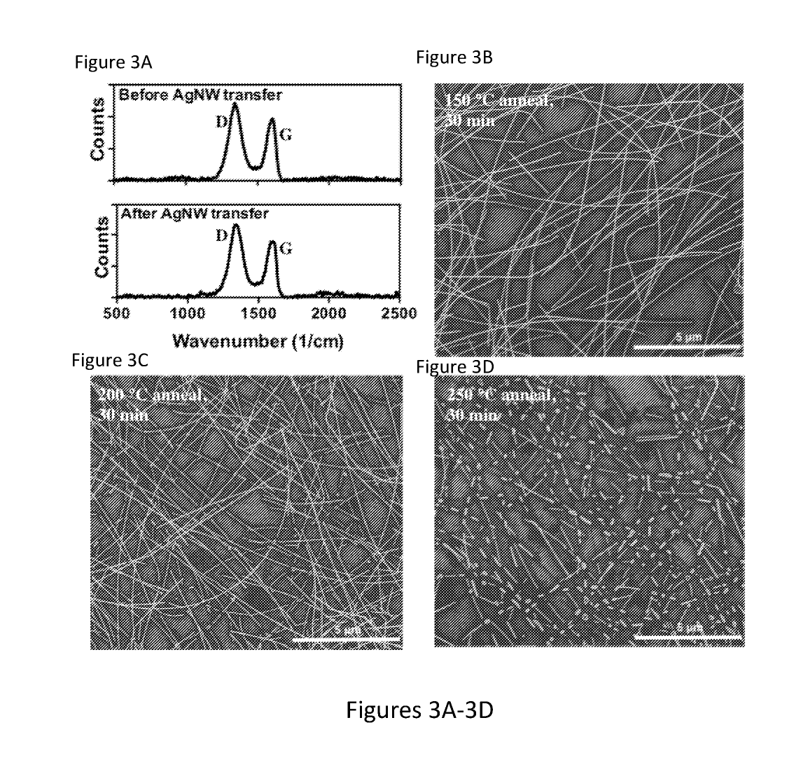

Fabrication of the porous electrode network was achieved by drawing down liquid solution with a Mayer rod onto a release glass substrate. First, a solution of graphene oxide (GO) was drawn down to act as a sacrificial layer when transferring the AgNW to PI matrix. FIG. 3A illustrates the Raman spectra before and after the transfer process to confirm the presence of GO with the same Raman intensity. The characteristic D and G bands of graphene oxide^{[25]} are present before and after transferring both pristine AgNW and ZnO—AgNW, confirming its use as a sacrificial layer. Following GO coating, a AgNW network was coated to a sheet resistance (Rₛₕ) of 10 ohm/square and 91% transparency (taking the GO coated glass as reference), as detailed in the Methods section. The solution-processed electrode on glass was subsequently brought into an ALD chamber for low temperature thermal deposition. Because ALD deposition relies exclusively on surface reactions, with hydroxylated surfaces typically being the most reactive with ALD precursors, a thin layer of aluminum oxide (Al₂O₃) was deposited as an adhesive layer prior to ZnO deposition. Al₂O₃ was selected as the adhesive layer as its precursor, trimethyl aluminum (TMA), has been shown to react well with Ag and provides a hydroxylated surface for subsequent deposition processes.^{[26,27]} ZnO was deposited immediately following Al₂O₃. Both materials were deposited using a low temperature thermal deposition process to prevent oxidation and melting of the AgNWs.

2. Characterization of the ZnO Coated AgNW Electrodes

The ZnO coated and pristine AgNW electrodes were heated at 150, 200, and 250° C. for 30 minutes to verify the stability of the electrodes at high temperatures. It has been reported that at temperatures above 180° C., a sharp increase in Rsh is observed due to the coalescence of the nanowires into discrete droplets and the formation of a thin oxide layer that decrease electrical performance.^{[13,20]} While both pristine (FIG. 3B) and ZnO coated AgNWs were found to remain intact in a percolating network at 150° C., the beginning of coalescence into isolated droplets and fragmented nanowires was observed at 200° C. (FIG. 3C), and complete conversion of nanowires into discrete Ag nanoparticles at 250° C. for pristine AgNWs, as seen in FIG. 3D.

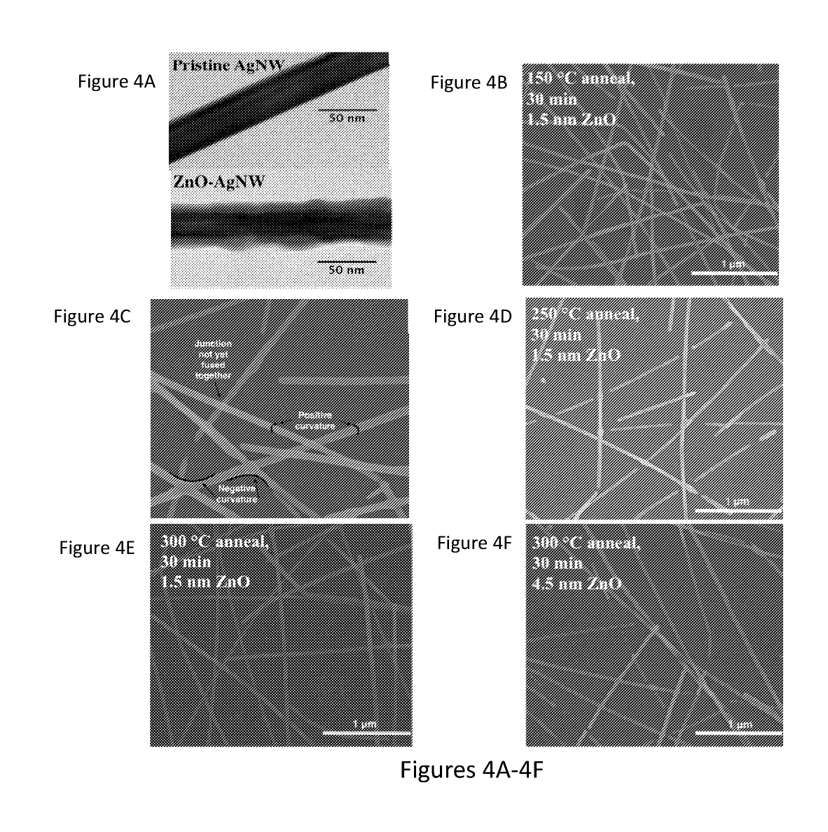

AgNW samples were coated with 1.0, 1.5, 3, 4.5, 6, and 7.5 nm of ZnO, and subsequently annealed at temperatures between 200 and 300° C. before SEM imaging to determine the minimum thickness of ZnO at which the additional thermal stability afforded to the AgNW remained intact. Silver was sputtered onto glass slides to be used as a reference before being brought into the ALD chamber to concurrently deposit ZnO on the reference and AgNW films. The thicknesses of ZnO layers were measured using a FilmTek 2000 ellipsometer. TEM images of AgNWs with and without ZnO are shown in FIG. 4A to illustrate the ZnO wrapping completely around the AgNW. A sample with 7.5 nm ZnO thickness measured with ellipsometry was imaged, matching well with the 7.8 nm measured from TEM. Though the bare AgNW shown is thicker than the ZnO coated AgNW, with different thicknesses of nanowires evident in SEM imaging as well (FIG. 4B), the ability to coat the desired ALD thickness on different dimension nanowires highlights the efficacy of this approach.

Standridge et al. conducted a study of ALD deposited TiO₂ on AgNW and found that below a certain thickness threshold, the resulting incomplete coverage of TiO₂ lead to significantly enhanced etching rates when placed in corrosive I⁻/I₃⁻ solutions.^{[27]} Similarly, it is hypothesized that below a certain thickness threshold for ZnO, incomplete coverage would enable the underlying Ag to melt and reform as discrete Ag droplets. While no samples showed adverse effects of annealing at 200° C., the beginning of junction deterioration was observed for samples with a ZnO thickness below 3 nm when annealed at 250° C. The melting and coalescence at the junction is believed to be caused in part by incomplete coverage of the protective ZnO coating at very low thicknesses. Because the AgNW film is comprised of layers of AgNWs stacked on top of each other, the bottom layers may not be exposed to precursor flow for long enough periods to render complete coverage, similar to high aspect nanostructures experiencing thinning regions in deeper portion of the nanostructure.^{[28,29]} In addition, the nanowires experience higher localized temperature at the junctions between individual nanowires. According to the Gibbs-Thomson theory, ΔG=2γΩ/r, where AG is the change in Gibbs Thomson potential, γ is the surface energy, Ω is the volume per atom, and r is the radius, the Gibbs-Thomson potential is inversely related to the radius of the nanowire. At the junction between nanowires, a negative curvature is present, leading to a negative value of the Gibbs-Thomson potential, as illustrated in FIG. 4C. However, the radius of individual nanowires is positive, leading to a positive Gibbs-Thomson potential, and thus, a large potential difference between the junction and regions immediately adjacent to the junction. This large potential gradient is a driving force for diffusion, causing the migration of atoms into the junction, which, over time, leads to the fragmentation of nanowires close to the junction. This phenomenon is clearly observed through the enlarged area around certain junctions, in addition to the discontinuity of select nanowires immediately adjacent to junctions as shown in FIG. 4D.

For samples heated to 300° C., partial coalescence of nanowires into droplets for samples with a ZnO thickness below 1.5 nm is observed. Again from the Gibbs-Thomson equation, it is known that the melting point of a nanowire is related to the radius of the nanowire.^{[30,31]} More specifically, the melting point of nanoparticles decreases with lower dimensions. In FIG. 4E, the formation of Ag nanoparticles is evident in nanowires with shorter radii. In comparison, FIG. 4F shows a 4.5 nm ZnO coated AgNW film annealed at 300° C. for 30 minutes with no significant fragmentation or coalescence of the nanowires. Though the bulk of the nanowire networks remained intact even with low thicknesses of ZnO, remaining experiments were conducted using AgNW electrodes coated with 4.5 nm of ZnO to ensure optimal performance.

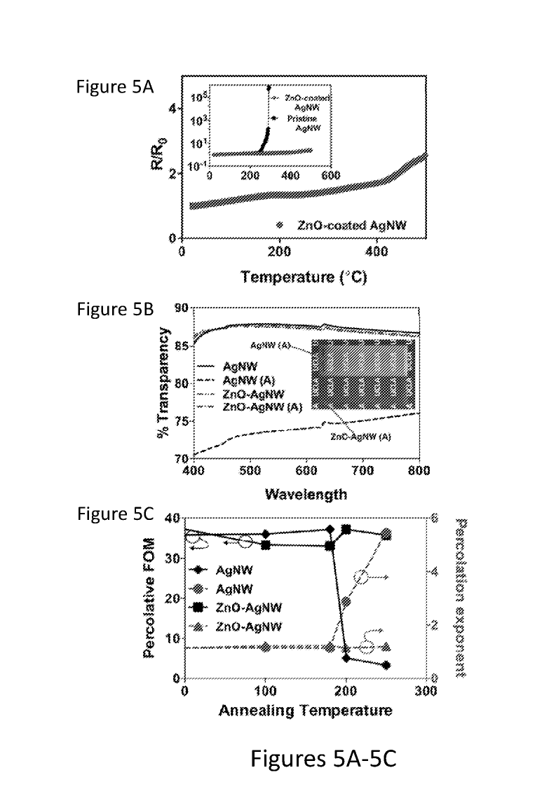

To quantitatively analyze the efficacy of the ALD coated AgNW film for high temperature processing, the sheet resistance and transmittance were evaluated and compared with pristine AgNWs before and after annealing. An electrical thermal stability test was performed by measuring the sheet resistance as a function of the annealing temperature to highlight the superior electrical performance of the ZnO—AgNW electrode. A ZnO—AgNW film coated on glass was annealed on an Instec mK1000 high precision temperature controller with a ramp rate of 5° C. min⁻¹. The hot stage was sealed with a cover on top under ambient conditions to prevent heat loss from the surface sample due to convection. Two electrical leads were formed on the samples with silver paste, with connections leading outside of the testing stage to measure the sheet resistance in situ every twelve seconds. In the case of the pure AgNW film, an increase in sheet resistance deviating from the slight increase of resistance associated with increasing temperature in metals was observed, with a dramatic increase in Rₛₕ beginning at 250° C. (FIG. 5A). At temperatures above 300° C., the sheet resistance exceeded the maximum measuring limit of the voltmeter. The ZnO enhanced electrode showed only the expected slight continuous increase in resistance as a function of temperature, with no rapid increase in resistance up to 500° C., at which the test was stopped due to the limitations of the instrument.

Though the poor electrical performance after high temperature annealing is largely attributed to the fragmentation of nanowires at temperatures above the melting point, atmospheric corrosion, primarily sulfidation and oxidation, which can occur at low temperatures, with increasingly deleterious effects with higher anneal temperatures, can also have detrimental effects for optoelectronic devices requiring high temperature processing.^{[32]} The corroded AgNW films, in addition to having increased sheet resistance, show significant transparency loss when compared to unannealed samples. In contrast, the ZnO—AgNW film exhibited excellent optical performance in the visible spectrum after annealing at 300° C. for 30 minutes, as seen in the inset of FIG. 5. Whereas the black background is clearly visible in the transparent ZnO coated electrode on the right, the control pristine AgNW sample subjected to the same annealing conditions is virtually fully opaque due to the atmospheric corrosion of silver by sulifdation and oxidation. Numerically, a 15 percent loss in transparency at a wavelength of 550 nm due to oxidation is observed in the non-coated AgNW when compared to non-coated, unannealed samples, as shown in FIG. 5B. However, the ZnO coated nanowire showed no decrease in transparency after annealing in contrast to pristine, unannealed AgNWs, showing its efficacy in protecting the underlying AgNWs not only from melting, but oxidation as well.

3. Percolation Characterization

The optoelectronic performance can be compared between the AgNW and control sample through comparison of the percolative figure of merit and percolation exponent, two parameters often used in describing optoelectronic performance of metal nanowires.^{[33]} These two parameters can be solved with the following equation:^{[15,33]}

$$T = {[ 1 + \frac{1}{Π} {( \frac{{Z}_{0}}{{R}_{sh}} )}^{\frac{1}{n + 1}} ]}^{- 2}$$

where Π and n are the percolative figure of merit (PFOM) and percolation exponent (PE), respectively, T is the optical transmittance, and Z₀ is the impedance of free space (377Ω). High values of II and low values of n are conducive to higher performing optoelectronic performance for metal nanowire based TCEs. Six pairs of Rₛₕ and T at each annealing temperature were used, and a curve fitted to obtain the respective PFOM and PE. As can be seen in FIG. 5C, the desirable trends for these two parameters are observed for ZnO-coated AgNW electrodes for different annealing temperatures, whereas a deterioration of the parameters is observed with higher annealing temperatures in the case of the pristine AgNWs.

4. Characterization of the Freestanding Electrode

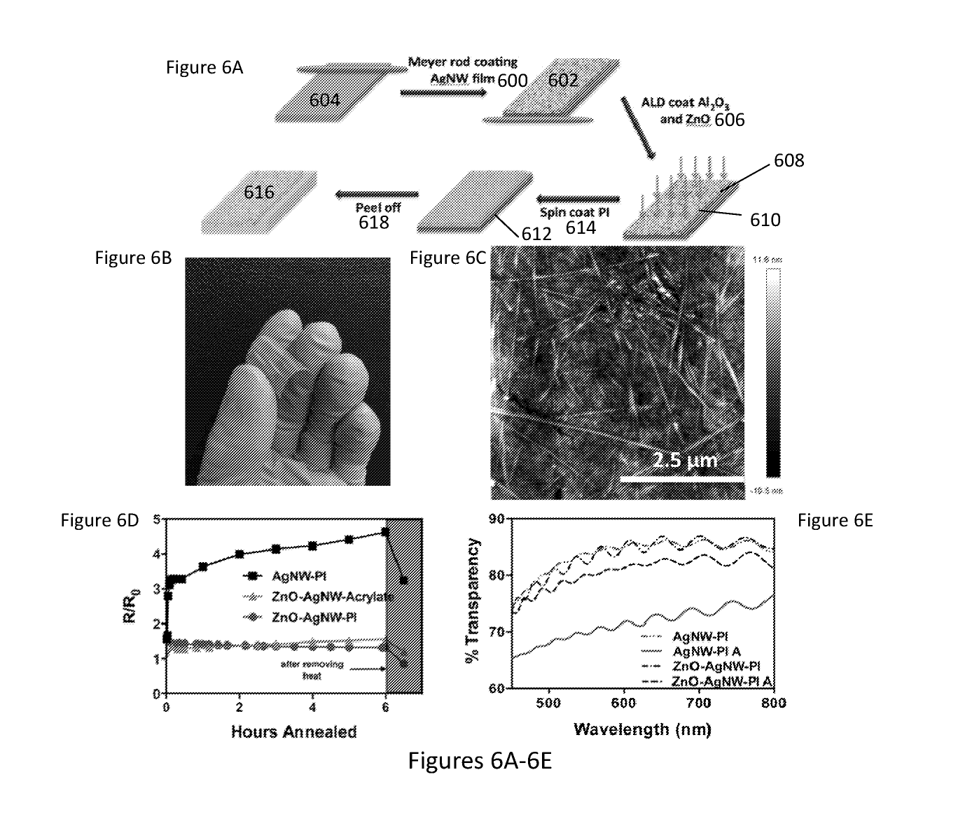

To create freestanding electrodes for optoelectronic devices, the coated nanowire networks were embedded and transferred from the glass substrate with a similar method reported in one of our previous publications, shown in FIG. 6A.^{[14]} FIG. 6A illustrates the method according to one or more embodiments, comprising Meyer rod coating 600 an AgNW film 602 onto a glass substrate 604, ALD coating 606 Al₂O₃ 608 and ZnO 610 onto the AgNW film 602 to form a ZnO—AgNW electrode 612, spin coating 614 a PI solution onto the ZnO—AgNW electrode 612, and heating at 130° C. in a vacuum oven to remove excess solvent. A freestanding ZnO—AgNW—PI film 616 was separated from the glass 604 after solvent removal, by peeling off 618 the film 616. The embedding of the ZnO coated AgNW into the surface of the PI allows for a sub-2 nm Rₐ topography (where Ra is defined as the arithmetic average of the absolute values), as shown in FIG. 6B, critical for the performance of certain optoelectronic devices such as OLEDs.

To evaluate the thermal stability with regards to electrical and optical performance of the freestanding composite hybrid electrode, the sheet resistance of the as-prepared films was analyzed in situ with the mK 1000 high precision temperature controller, and UV-vis spectra were obtained before and after annealing. The efficacy of both thermally stable components, PI and ZnO, were evaluated by comparing the ZnO—AgNW—PI films with three control electrodes: a pristine AgNW—PI film, a ZnO—AgNW-acrylate film, and a AgNW-acrylate film. The acrylate utilized in the reference electrode was previously used for flexible PLED devices with enhanced light extraction in a previous publication by two of the inventors.^{[14]} ZnO-coated AgNW films were heated at 300° C., for 6 hours, while the reference films with pristine AgNW were heated to 250° C. also for 6 hours, due to the inability of bare AgNWs to withstand higher temperatures. Regarding electrical stability, the AgNW-acrylate films failed in the first few minutes, with the resistance increasing over 10 MΩ, the limit of the voltmeter used to measure the resistance. FIG. 6D shows the change in sheet resistance as a function of time for the two other reference electrodes, and the ZnO—AgNW—PI electrode. The AgNW—PI showed a linear increase in sheet resistance, with the final resistance after cooling back down to room temperature more than three times the original sheet resistance. The AgNW—PI electrode was also tested at 300° C., where similar to the AgNW-acrylate films, the electrode failed to register a resistance within a few minutes. In contrast, the ZnO coated films showed significantly better electrical performance, with the ZnO-acrylate electrode increasing in sheet resistance by only 21%, and the ZnO—AgNW—PI decreasing in sheet resistance by 15%. This decrease in sheet resistance is attributed to the fusing of nanowires at the junction, as the high annealing temperature allows the non-coated regions at the point of intersection of the nanowires to melt and fuse together, while the outer ZnO shell prevents the complete melting of the nanowires. The fusing of nanowires at the junction lowers the junction resistance of the nanowires, which in turn, lowers the overall sheet resistance of the electrode.

In addition to the electrical stability, the ZnO—AgNW—PI electrode was also able to withstand the 6 hour anneal at 300° C. without significant optical deterioration of the films, as seen in the UV-vis spectra in FIG. 6E. FIG. 6E illustrates a control AgNW—PI electrode before and after heating at 250° C., along with the ZnO—AgNW—PI electrode before and after heating at 300° C. to demonstrate the efficacy of ZnO in preventing oxidation of the nanowires within the PI polymer matrix. The wave-like characteristics of the spectrum are characteristic of the PI polymer.^{[34]} For the pristine AgNW embedded within the PI matrix, a 14.4% decrease in transparency is observed before and after heating at 250° C., in contrast to a 1.9% loss in transparency in the ZnO—AgNW—PI freestanding electrode after heating at 300° C. An AgNW-acrylate, and ZnO—AgNW-acrylate electrode were also analyzed before and after heating at 250° C. to highlight the thermal resistance of the PI substrate. The acrylate substrate exhibited significant yellowing of the film, quantified by a 31% transparency loss for the ZnO—AgNW-acrylate electrode, and a 43% loss for the pristine AgNW-acrylate electrode. This yellowing in the acrylate is a deterioration often observed in plastic films due to radical-activated oxidative degeneration of the hydrocarbon backbone in the polymer material.^{[35]}

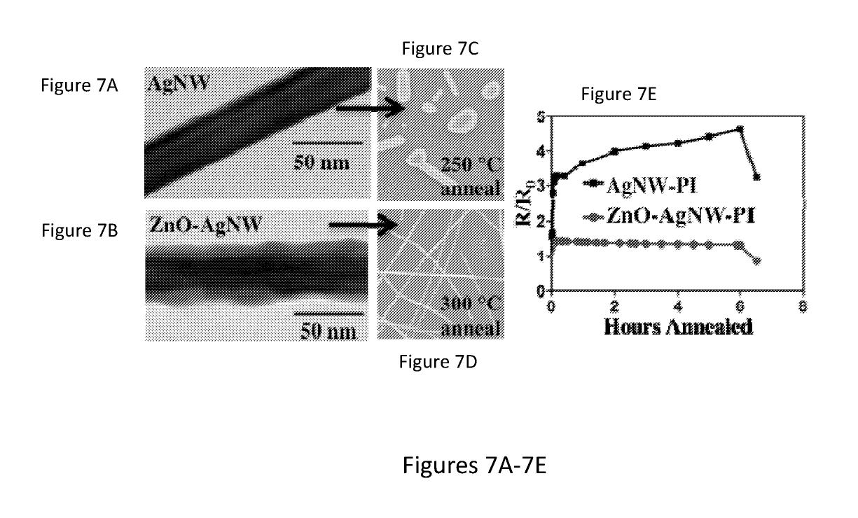

FIGS. 7A-7E compare the structure and electrical performance of pristine AgNW and ZnO—AgNW, wherein FIG. 7A is a TEM image of pristine AgNW, FIG. 7B is a TEM of ZnO—AgNW, FIG. 7C is an SEM image of pristine AgNW after annealing at 250° C., FIG. 7D is an SEM image of ZnO—AgNW after annealing at 300° C., and FIG. 7E compares the sheet resistance of an AgNW—PI film and a ZnO—AgNW—PI film.

5. PLED Fabrication and Characterization

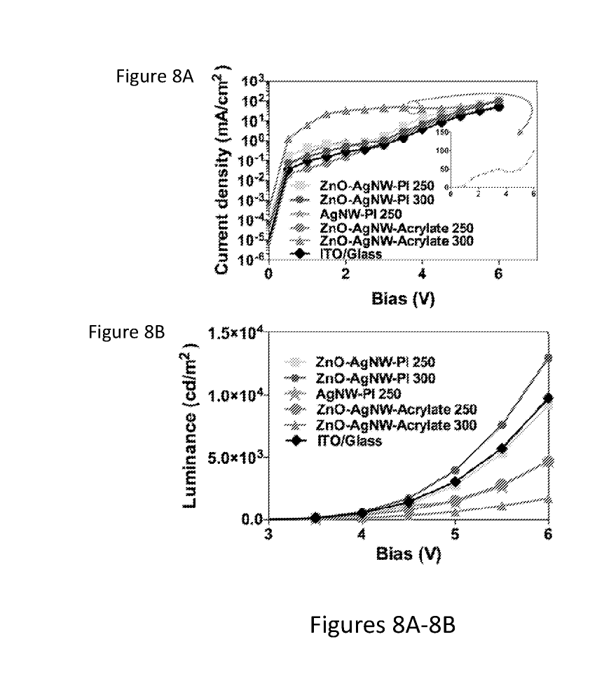

To demonstrate the viability of the ZnO—AgNW—PI film as a flexible TCE, solution-processed white PLEDs were fabricated in a typical bottom-emissive structure. Solution processed bis(acetylacetonato) dioxomolybdenum(VI) [MoO₂(acac)₂] was used as the precursor for the hole injection layer, and was seen empirically from thermogravimetric analysis (TGA) and x-ray photoelectron spectroscopy (XPS) to require a minimum temperatures of 250° C. to begin the conversion to MoOₓ. This solution processed MoOₓ (s-MoOₓ) has been reported as an effective hole-injection material to enhance hole injection in OLEDs and hole collection in organic photovoltaic cells.^{[36,371]} Detailed procedures of materials for the s-MoOₓ and the PLED fabrication processes are described in the Method section. The white PLEDs were fabricated on five different substrates: a ZnO—AgNW—PI hybrid electrode; a ZnO—AgNW-acrylate electrode, a pristine AgNW—PI electrode, the pristine AgNW-acrylate electrode used in a previous paper by two of the inventors;^{[14]} and sputtered ITO on a glass substrate. All polymer based electrodes were analyzed after heating the MoO₂(acac)₂ precursor both at 250° C. and 300° C. Characteristic current density (J-V) and luminance-voltage curves are shown in FIGS. 8A and 8B, respectively. Data for PLEDs based on the pristine AgNW-acrylate electrode at both temperatures, in addition to the pristine AgNW—PI electrode at 300° C. are not shown as no light could be observed from these devices due to the immeasurably high resistance of the electrodes as discussed above.

For the ZnO—AgNW—PI electrode, enhanced luminance at the higher annealing temperature was observed due to the formation of Mo⁴⁺ and Mo⁵⁺ species at higher temperatures. These reduced species lead to the formation of gap states in MoOₓ, lowering the potential barrier height in contrast to what is expected from the phenomenological model, and in turn, enhancing PLED performance for devices annealed at higher temperatures and longer annealing times. The PLED based on the AgNW—PI electrode annealed at 250° C. was capable of light emission, though an increased resistance and decreased transparency resulted in a 63.7% lower luminance at 6 V as compared to the ZnO—AgNW—PI annealed at 300° C. ZnO—AgNW-acrylate based diodes were capable of light emission at both annealing temperatures, though significant transparency loss for both samples annealed at 250° C. and 300° C. resulted in a 64.0% and 87.0% luminance loss at 6 V, respectively, in contrast with the ZnO—AgNW—PI based diode. Furthermore, with higher annealing temperatures, the presence of localized shorts in the devices was observed, as seen in the inset of FIG. 8A. These shorts in the device may also contribute to the lower luminance, as illustrated in FIG. 8B. The ZnO—AgNW—PI electrode annealed at 300° C. exhibited similar luminance to ITO using the same device structure and processing conditions. The maximum external quantum efficiency (EQE) and current efficiency (CE) for ITO based devices was 7.7% and 14.7 cd/A, while corresponding efficiencies for the ZnO—AgNW—PI PLED was 6.9% and 13.2 cd/A. All other EQEs and CEs for PLEDs based on reference electrodes were under 5% and 10 cd/A, respectively. The comparable performance of the ZnO—AgNW—PI PLED (according to one or more embodiments of the present invention) and an ITO/glass PLED with the same processing condition verifies the new composite substrate's efficacy for use in optoelectronic devices requiring high processing temperatures. It is expected that significantly improved performance can further be obtained with the dispersion of nanoparticles within the polymer matrix to enhance light extraction.^{[14]} The inventors of the present invention anticipate that the ZnO—AgNW—PI composite electrode can be used for emerging flexible optoelectronic devices requiring high temperature fabrication processing in a transition away from conventional TCE materials.

Thus, one or more embodiments of the invention have fabricated a TCE for high performance optoelectronic devices requiring high processing temperatures, wherein the TCE is comprised of AgNW coated with a thin, conformal layer of ZnO deposited with ALD, and embedded within a PI matrix. Enhanced thermal stability for this TCE based on electrical and optical performance of the ZnO coated AgNW film was observed. The freestanding ZnO—AgNW—PI film also showed excellent thermal stability in regards to both electrical and optical performance. Because the high temperature stable AgNWs are embedded within the PI, the resulting TCE has a smooth surface topography, allowing its use for optoelectronic devices requiring smooth interfaces.

As proof of viability, a white PLED was fabricated on the ZnO—AgNW—PI film comprising a layer of MoOₓ processed from solution followed by annealing at 250 or 300° C. The PLED exhibited comparable performance to controls on ITO/glass, and vastly outperforming control devices with one or no thermally stable component (ZnO and PI). The ZnO—AgNW—PI electrode shows great promise for replacing ITO as it ameliorates a significant limitation of flexible, plastic TCEs hindering their widespread adoption-low thermal stability.

6. OLEDs on a Glass Substrate

To address barrier property needs of the TCE, similar integrated electrodes have further been fabricated on a glass substrate. With this embodiment of the TCE, the glass residing below the electrical component constitutes the thermally stable substrate providing the electrode with robust mechanical properties. The glass substrate can range in thickness from Willow® Glass having a thickness of 100 microns or less, to touchscreen glass, to microscope glass (having approximately 1 mm thickness). Depending on the glass substrate used, the resulting TCE can be made flexible (e.g., Willow® Glass) or rigid. A thin acrylate layer is covalently bonded to the glass substrate with 3-(trichlorosilyl)propyl methacrylate, with the thickness of the acrylate controlled by various wet processing methods such as spin coating, drop casting, dip coating, bar coating, or doctor blading. Similar to the aforementioned thermally stable TCE, a ZnO-coated AgNW layer can be embedded in the top surface of the acrylate, providing the TCE with thermal protection in addition to barrier properties.

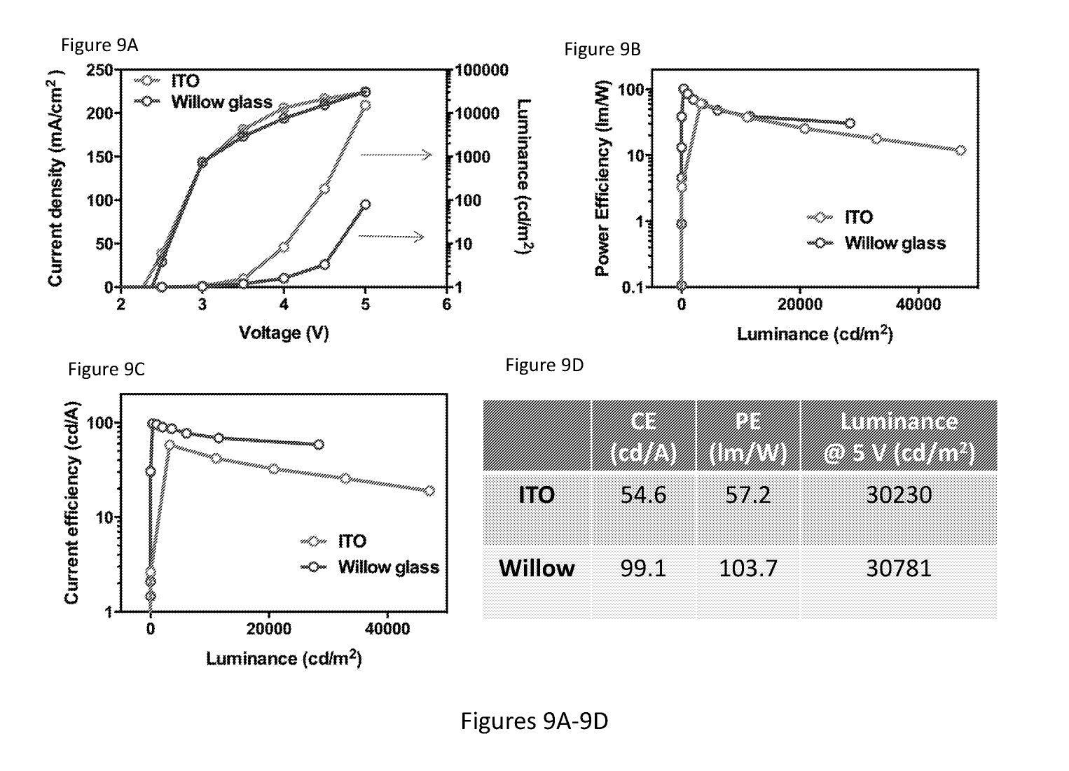

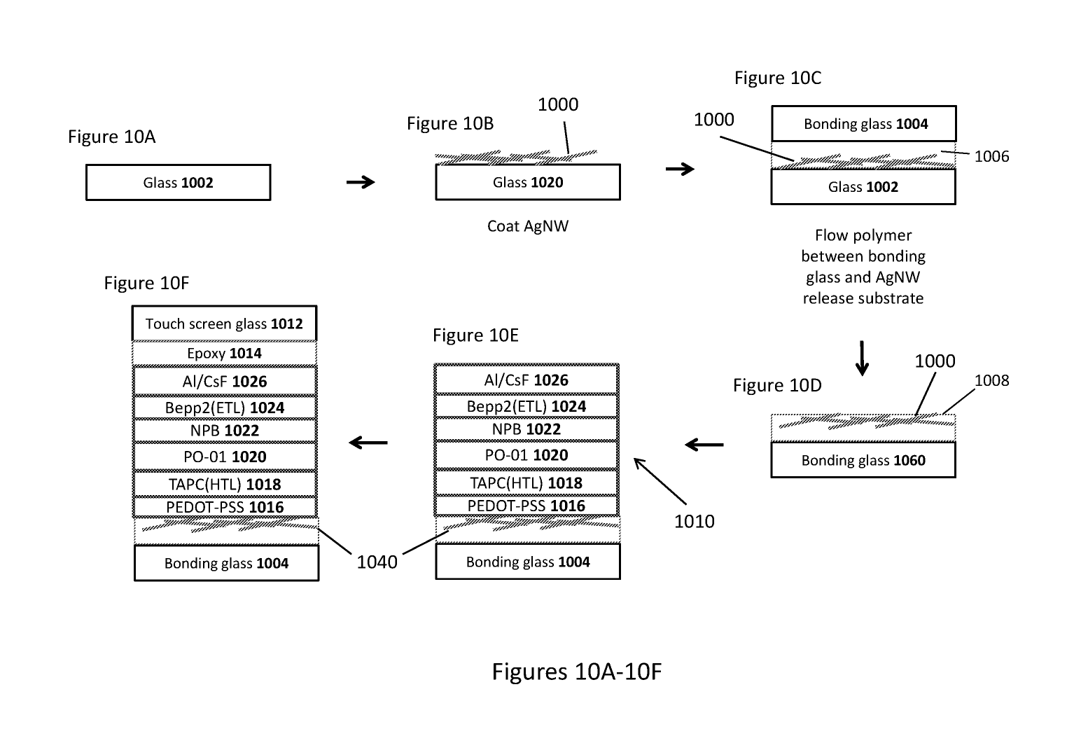

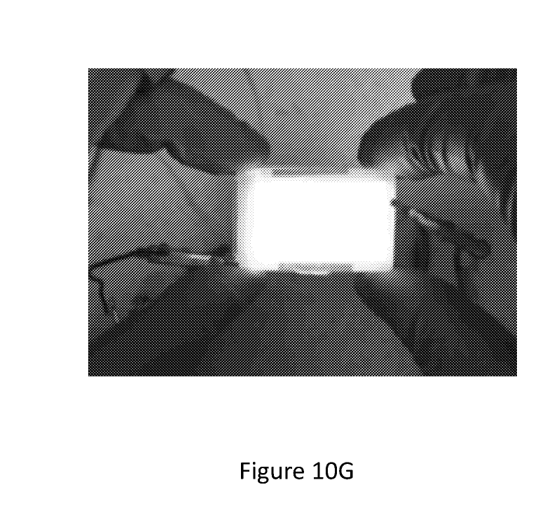

In addition to addressing the three limitations of AgNW based electrodes described previously (poor thermal stability, high surface roughness, and lack of barrier properties), the glass-based integrated substrate is capable of more aggressive processing due to the robust nature of the substrate, and can incorporate internal light extraction mechanisms. Though the glass substrates limit the flexibility of the TCE, at this point in time, highly flexible substrates are not required in the marketplace. Rather, rigid, or slightly curved substrates that can be conformally deployed on various surfaces are desired, a technology still possible with (Willow® Glass) substrates. Furthermore, light extraction particles can be incorporated within the polymer matrix embedding the AgNWs, allowing for OLED efficiencies more than twice that obtainable with ITO substrates. As a proof of concept, white OLED devices were fabricated on a substrate integrated with the anode structure: Willow® Glass; self assembled monolayer (SAM) used for bonding the polymer to glass; polymer with nanoparticles dispersed within the polymer; and AgNW at the surface. FIGS. 9A-D illustrate the resulting performance of the white OLED, showing current and power efficiencies approximately twice that obtained with the control ITO based device. With this structure, an additional layer of bonding glass can be attached on the cathode surface and sealed with epoxy, representing an entirely glass sealed OLED. FIGS. 10A-F illustrate the fabrication process of such a device, in addition to a photograph (FIG. 10G) of a fully encapsulated white OLED fabricated on a microscope glass slide, tested in ambient air. The fabrication steps include coating AgNW 1000 on a glass substrate 1002 (FIG. 10B), attaching bonding glass 1004 (release substrate) such that the AgNW 1000 are sandwiched between the glass substrate 1002 and the bonding glass 1004, and flowing polymer 1006 between the bonding glass and the glass substrate (FIG. 10C), removing the glass substrate (FIG. 10D) to expose a conductive surface 1008 comprising the AgNWs 1000, depositing a light emitting device structure 1010 on the conductive surface 1008 (FIG. 10E), and attaching glass 1012 (touch screen glass) to the light emitting device structure using epoxy 1014 (FIG. 10F). The light emitting device structure deposited in FIG. 10E comprises a PEDOT:PSS layer 1016, a 4,4′-Cyclohexylidenebis[N,N-bis(4-methylphenyl)benzenamine] (TAPC) Hole Transport Layer (HTL) 1018, a yellow phosphor comprising Iridium (III) bis(4-phenylthieno [3,2-c]pyridinato-N,C2′)acetylacetonate (PO-O1) 1020, a 1,4-bis(1-naphthylphenylamino)biphenyl (NPB) active layer 1022, a bis[2-(2-hydroxyphenyl)-pyridine] beryllium (Bepp2) electron transport layer (ETL) 1024, and an Al/CsF layer 1026.

Supplementary Information on Methods and Materials

Raw Materials.

GO was prepared from graphite by the modified Hummers method.^{[38]} AgNWs were purchased from Zhejiang Kechuang Advanced Materials Co., LTD. PI was obtained from Nexolve Materials. 2,2-Dimethoxy-2phenylacetophenone (photoinitator), anhydrous chlorobenzene, chlorobenzene, and bis(acetylacetonato) dioxomolybdenum(VI) were obtained from Sigma-Aldrich. PEDOT:PSS (Clevios VP AL4083) was purchased from H.C. Starck Inc. Zonyl FS-300 fluorosurfactant was purchased from Fluka Analytical. A white-light-emitting polymer (WP) was provided by Cambridge Display Technology, and 1,3-bis[(4-tert-butylphenyl)-1,3,4-oxidiazolyl)phenylene (OXD-7) was obtained from Lumtech. Materials for white-light OLEDs were obtained from Lumtech. Willow® Glass was obtained from Corning®. 3-(Trichlorosilyl)propyl mechacrylate was purchased from Sigma-Aldrich. Barium strontium titanate light extraction nanoparticles were obtained from TPL Inc. Acrylate monomers were obtained from Sartomer.

Preparation of ZnO—AgNW Networks and Freestanding ZnO—AgNW—PI Composite Electrodes.

GO powder was dispersed in deionized (DI) water at a concentration of 2 mg/mL in an ultrasonic bath for 15 minutes. The resulting solution was further diluted with isopropyl alcohol (IPA) to 0.2 mg/5 mL, and sonicated for 15 minutes before use. A glass slide was placed flat, and the solution of GO drop-casted into a thin line at the top of glass and drawn down with a Meyer rod. The resulting films were annealed on a hot plate at 150° C. for 30 minutes. Subsequently, AgNW solution was drawn down on the GO covered glass slide prior to annealing at 150° C. for 3 minutes, soaking in DI water for 10 minutes, and a second annealing at 165° C. for 8 minutes. GO-AgNW slides were introduced into a Fiji ALD chamber from Cambridge NanoTech. Al₂O₃ was deposited at 100° C. from TMA and H₂O precursors, with pulse and purge times for the two precursors both being 0.06 and 30 s. ZnO was deposited at 100° C. following Al₂O₃ deposition from (C₂H₅)₂Zn, diethyl zinc (DEZ) and H₂O, with pulse times for the two precursors being 0.06/45 seconds (s), and 0.06/60 s, respectively.

PI solution was made by dissolving 20% PI in chlorobenzene. The soluble PI was spun onto the ZnO—AgNW or bare AgNW coated glass before peeling off

Fabrication of White PLED.

In a procedure for the ZnO—AgNW—PI electrode based devices according to one or more embodiments of the present invention described above, freestanding electrodes were cleaned in an ultrasonic bath with detergent and DI water for 30 minutes, before being soaked and rinsed with ethanol. A solution of 0.3 wt % MoO₂(acac)₂ in IPA was spin-coated on the substrate at 2000 rpm for 60 s, and then annealed at 250° C. or 300° C. for 1 hr. The films were next spun with a solution of 2000:1 vol % (PEDOT:PSS):(Zonyl FS-300) at 1100 rpm for 30 seconds, followed by annealing at 130° C. for 30 min to dry off any residual solvent. The white polymer emissive layer was spun from a solution of 100:10 wt % WP:OXD-7 in chlorobenzene. A 1 nm layer of cesium fluoride (CsF) and 100 nm of aluminum (Al) were evaporated onto the substrate through a shadow mask at 10⁻⁶ Torr.

Preparation of Integrated Substrate on Glass.

A glass slide was immersed in a solution comprising 2 wt. % 3-(Trichlorosilyl)propyl mechacrylate in toluene for 30 minutes. After removal from solution, the glass was cleaned with acetone and IPA. A separate glass slide used as a release substrate was coated with AgNW following the procedure described above. An acrylate monomer solution was formed by admixing BST nanoparticles into the monomer at 5 wt % concentration. The resulting monomer dispersion was infiltrated between the release glass substrate with AgNW and the Self Assembled Monolayers (SAM) treated glass substrate, followed by exposure to ultraviolet radiation to convert the solution into a cross-linked polymer matrix. The AgNW electrode was peeled off the release glass substrate, yielding a TCE with glass substrate and embedded AgNW on the surface.

Fabrication of White OLED and Encapsulation.

In a typical procedure for the integrated glass substrate based devices described above, freestanding electrodes were cleaned in an ultrasonic bath with detergent and DI water for 30 minutes, before being soaked and rinsed with acetone and IPA. The films were next spun with a solution of PEDOT:PSS at 4000 rpm for 1 min, followed by annealing at 130° C. for 30 min to dry off any residual solvent. The PEDOT:PSS coated substrates were brought into an evaporation chamber, where the structure TAPC/PO-01/NPB/Bepp₂/CsF/A1 was evaporated. For encapsulated devices, a thin layer of UV-sensitive epoxy was applied surrounding the active area, and a piece of glass sandwiched on top. The device was placed under ultraviolet irradiation for 5 min before being brought into ambient atmosphere for testing.

Characterization Methods.

Scanning electron microscopy (SEM) was performed on a JOEL JSM-6701F scanning electron microscope. Transmittance spectra were obtained with a Shimadzu UV-1700 spectrophotometer. Surface topography was carried out on a Dimension Icon Scanning Probe Microscope (SPM) from Bruker. Electrical measurements for the white PLED were carried out in a nitrogen atmosphere glovebox, with the current and light voltage curves being measured with a Keithley 2400 source meter and calibrated silicon photodetector by sweeping the applied voltage from 0 to 6 V at 500 millivolt (mV) increments per step. All characterization tests were carried out at room temperature.

Advantages and Improvements

Silver nanowires (AgNW) have emerged as a key material to fabricate transparent electrodes, to replace indium tin oxide (ITO) coated on glass or polyester (PET), due to their mechanical flexibility, reduced cost, and higher performance. These AgNW porous networks on a plastic substrate have been extensively developed and commercialized for touch sensors. U.S. Patent Publication No. 20130251943 (corresponding to U.S. patent application Ser. No. 13/783,284 and UC Ref. No. 2011-133 cross-referenced above) provides, in one or more examples, a unique approach for fabricating transparent electrodes based on (e.g., silver) nanowires for low cost manufacturing of devices such as touch sensors and transparent substrates for organic thin film devices such as organic light emitting diodes (OLEDs). U.S. Patent Publication No. 20150207106 (corresponding to U.S. patent application Ser. No. 14/600,194 and UC Ref. No. 2013-001 cross-referenced above) significantly increases the light extraction efficiency of the OLEDs in one or more examples.

High thermal stability is essential for the commercialization of this technology. Silver nanowires are slowly oxidized or sulfidated in ambient conditions, with the deterioration process significantly accelerating at elevated temperatures between 200-300° C. These elevated temperatures are often employed in industry processes to deposit, anneal, and/or pattern thin films, and can result in the melting of silver nanowires, particularly at the junction.

U.S. Patent Publication No. 20130251943 (corresponding to U.S. patent application Ser. No. 13/783,284 and UC Ref. No. 2011-133 cross-referenced above) and U.S. Patent Publication No. 20150207106 (corresponding to U.S. patent application Ser. No. 14/600,194 and UC Ref. No. 2013-001 cross-referenced above) concern the preparation and application of (e.g., silver) nanowire-polymer composite electrodes. One limitation previously unaddressed is the thermal instability of silver nanowires due to atmospheric corrosion and the resulting impact on electrical performance. The resulting transparent electrode is thus unsuitable for device fabrication or operation involving a high temperature process. When subjected to high temperature processes, both surface conductivity and optical transparency exhibit major losses when exposed to temperatures in excess of 180° C. This deterioration occurs even at ambient conditions, albiet at a slower pace, often observable after a month duration of shelf storage. One or more embodiments of the present invention provide a solution to thermal deterioiration of silver nanowire-polymer composite electrodes by conformally coating of a thin layer of zinc oxide by ALD to protect the silver nanowires. The resulting transparent electrode can survive processing temperatures as high as 300° C. One or more embodiments of the present invention also provide a thermally stable substrate such as flexible glass for the silver nanowires.

U.S. Pat. Nos. 8,957,318, 8,957,315, and patent publication Nos. 20140205845, 20140199555, 20140199555, 20140170407, 20140072826, and 20140170427 (incorporated by reference herein) teach that anticorrosion agents in conjunction with silver nanowires for transparent conductive films can be utilized to protect the transparent conductive film from electrical degradation as a result of oxidation or other forms of corrosion. The anticorrosion agents used, respectively, for the patents and applications listed above are zinc salts, boric acid, certain phenolic compounds, tri-halo aromatic compounds, certain mercaptotetrazoles and mercaptotriazoles, 1,2-Diazmine compounds, and organic acids, though none of the above compounds have addressed the issue of thermal stability of the silver nanowires, with testing occurring at a maximum of 80 degrees centigrade. U.S. Patent Publication No. 20140202738 teaches that having the silver nanowires embedded in a thermally stable polymer, with an overcoat on top, wherein at least one of the polymer binder or overcoat layer is thermally stable, can produce a thermally stable transparent conductive electrode. However, the use of an overcoat layer complicates the structure, makes the surface rougher, and the transparent conductive electrode tested was only tested at a maximum temperature of 400° C. for four minutes. Moreover, the structure does not address the thermal stability of the silver nanowires. Even if the plurality of layers used was able to adequately protect against electrical degradation, which was not shown in the publication, the transparency of the transparent conductive electrode should drop significantly when tested for periods in excess of four minutes, as the change in transparency for the silver nanowires should itself total an approximately 10 percent decrease.

One or more embodiments of the present invention describe a novel approach to increase the thermal stability of silver nanowires by conformal coating of zinc oxide by atomic layer deposition. This process according to one or more embodiments of the present invention does not alter the nanowire porous network structure and thus allows for subsequent infiltration by a polymer solution to embed the network in the polymer substrate, resulting in a transparent conductive electrode with a sub 2 nm roughness surface. One or more embodiments of the present invention additionally provide a flexible substrate for the silver nanowire networks with high thermal stability. In one or more embodiments, a thermally stable (e.g., silver nanowire-polyimide) transparent electrode can be prepared by (1) depositing a (e.g., silver) nanowire porous network on a release substrate; (2) conformally coating a thin layer of a protective layer onto the (e.g., silver) nanowires (e.g., using ALD); (3) applying a liquid solution containing a polymer or curable polymer precursor; and (4) removing the resulting polymer coating from the release substrate to transfer the silver nanowire network onto the polymer coating.

One or more embodiments of the present invention disclose a transparent conductive film having the combination of (1) low sheet resistance (e.g., sheet resistance of 50 Ohms per square or less), (2) thermally stable sheet resistance (e.g., sheet resistance that degrades by no more than 5% when heated to 250° C. for 1 hour, (3) thermally stable transmittance (e.g., transmittance at a wavelength of 550 nm that decreases by no more than 5% when heated to 250° C. for 1 hour), and (4) low surface roughness (e.g., less than 2 nm). This combination of low and thermally stable sheet resistance, thermally stable transmittance, and low surface roughness is surprising and unexpected in view of the above described deficiencies (e.g., high surface roughness) in previously reported work (see e.g., at least^{[19,22,23, 42]}).

### REFERENCES

The following references are incorporated by reference herein.
[1] L. Hu, H. Wu, Y. Cui, MRS Bull. 2011, 36, 760.
[2] A. Kumar, C. Zhou, ACS Nano 2010, 4, 11.
[3] T. Hamaguchi, K. Omae, T. Takebayashi, Y. Kikuchi, N. Yoshioka, Y. Nishiwaki, a Tanaka, M. Hirata, O. Taguchi, T. Chonan, Occup. Environ. Med. 2008, 65, 51.
[4] Z. Chen, Thin Solid Films 2001, 394, 201.
[5] K. Ellmer, Nat. Photonics 2012, 6, 808.
[6] M. W. Rowell, M. a. Topinka, M. D. McGehee, H. J. Prall, G. Dennler, N. S. Sariciftci, L. Hu, G. Gruner, Appl. Phys. Lett. 2006, 88, 86.
[7] D. Zhang, K. Ryu, X. Liu, E. Polikarpov, J. Ly, M. E. Tompson, C. Zhou, Nano Lett 2006, 6, 1880.
[8] K. S. Kim, Y. Zhao, H. Jang, S. Y. Lee, J. M. Kim, K. S. Kim, J.-H. Ahn, P. Kim, J.-Y. Choi, B. H. Hong, Nature 2009, 457, 706.
[9] S. Bae, H. Kim, Y. Lee, X. Xu, J.-S. Park, Y. Zheng, J. Balakrishnan, T. Lei, H. R. Kim, Y. Il Song, Y.-J. Kim, K. S. Kim, B. Ozyilmaz, J.-H. Ahn, B. H. Hong, S. Iijima, Nat. Nanotechnol. 2010, 5, 574.
[10] J. Zou, H. L. Yip, S. K. Hau, A. K. Y. Jen, Appl. Phys. Lett. 2010, 96, 3.
[11] M. Song, J. H. Park, C. S. Kim, D.-H. Kim, Y.-C. Kang, S.-H. Jin, W.-Y. Jin, J.-W. Kang, Nano Res. 2014, 7, 1370.
[12] J. Liang, L. Li, X. Niu, Z. Yu, Q. Pei, Nat. Photonics 2013, 7, 817.
[13] H.-G. Im, J. Jin, J.-H. Ko, J. Lee, J.-Y. Lee, B.-S. Bae, Nanoscale 2014, 6, 711.
[14] L. Li, J. Liang, S.-Y. Chou, X. Zhu, X. Niu, Z. Yu, Q. Pei, Sci. Rep. 2014, 4, 4307.
[15] H. Im, S. Jung, J. Jin, D. Lee, J. Lee, D. Lee, J. Lee, ACS Nano 2014, 10973.
[16] X. Y. Zeng, Q. K. Zhang, R. M. Yu, C. Z. Lu, Adv. Mater. 2010, 22, 4484.
[17] J. Li, J. Liang, X. Jian, W. Hu, J. Li, Q. Pei, Macromol. Mater. Eng. 2014, 299, 1403.
[18] Z. Yu, L. Li, Q. Zhang, W. Hu, Q. Pei, Adv. Mater. 2011, 23, 4453.
[19] Q. Huang, W. Shen, X. Fang, G. Chen, Y. Yang, J. Huang, R. Tan, W. Song, ACS Appl. Mater. Interfaces 2015, 7, 4299
[20] J. Y. Lee, S. T. Connor, Y. Cui, P. Peumans, Nano Lett. 2008, 8, 689.
[21] J. Chen, H. Ahn, S. Yen, Y. Tsai, 2014, 6, 20995.
[22] A. Kim, Y. Won, K. Woo, C. H. Kim, J. Moon, ACS Nano 2013, 7, 1081.
[23] Q. Xu, W. Shen, Q. Huang, Y. Yang, R. Tan, K. Zhu, N. Dai, W. Song, J. Mater. Chem. C 2014, 2, 3750.
[24] S. Chen, L. Song, Z. Tao, X. Shao, Y. Huang, Q. Cui, X. Guo, Org. Electron. 2014, 15, 3654.
[25] Z. Ji, X. Shen, M. Li, H. Zhou, G. Zhu, K. Chen, Nanotechnology 2013, 24, 115603.
[26] A. V. Whitney, J. W. Elam, P. C. Stair, R. P. Van Duyne, J. Phys. Chem. C 2007, 111, 16827.
[27] S. D. Standridge, G. C. Schatz, J. T. Hupp, Langmuir 2009, 25, 2596.
[28] I. Perez, E. Robertson, P. Banerjee, L. Henn-Lecordier, S. J. Son, S. B. Lee, G. W. Rubloff, Small 2008, 4, 1223.
[29] H. Y. Lee, C. J. An, S. J. Piao, D. Y. Ahn, M. T. Kim, Y. S. Min, J. Phys. Chem. C 2010, 114, 18601.
[30] T. Bin Song, Y. Chen, C. H. Chung, Y. Yang, B. Bob, H. S. Duan, G. Li, K. N. Tu, Y. Huang, ACS Nano 2014, 8, 2804.
[31] M. Zhao, X. H. Zhou, Q. Jiang, J. Mater. Res. 2001, 16, 3304.
[32] J. L. Elechiguerra, L. Larios-Lopez, C. Liu, D. Garcia-Gutierrez, A. Camacho-Bragado, M. J. Yacaman, Chem. Mater. 2005, 17, 6042.
[33] S. Sorel, P. E. Lyons, S. De, J. C. Dickerson, J. N. Coleman, Nanotechnology 2012, 23, 185201.
[34] C. P. Ennis, R. I. Kaiser, Phys. Chem. Chem. Phys. 2010, 12, 14884.
[35] S. Yang, S.-Y. Kwak, J. Jin, J.-S. Kim, Y. Choi, K.-W. Paik, B.-S. Bae, J. Mater. Chem. 2012, 22, 8874.
[36] K. Zilberberg, H. Gharbi, A. Behrendt, S. Trost, T. Riedl, ACS Appl. Mater. Interfaces 2012, 4, 1164
[37] M. Takayama, S. Naka, H. Okada, Jpn. J Appl. Phys. 2013, 52, 1.
[38] D. a Dikin, S. Stankovich, E. J. Zimney, R. D. Piner, G. H. B. Dommett, G. Evmenenko, S. T. Nguyen, R. S. Ruoff, Nature 2007, 448, 457.
[39] U.S. Pat. No. 8,957,318, entitled “Stabilization agents for silver nanowire based transparent conductive films” (see e.g., abstract and claim 1).
[40] U.S. Pat. No. 8,957,315, entitled “Stabilization agents for silver nanowire based transparent conductive films” (see e.g., abstract and claim 1).
[41] U.S. Patent Application Publication No. 20140205845, entitled “Stabilization agents for transparent conductive films,” (see e.g., abstract and claims 1, 6, 10, 8, 9, 10).
[42] U.S. Patent Application Publication No. 20140202738, entitled Nanostructure transparent conductors having high thermal stability for esd protection (see e.g., claims 1-11).
[43] U.S. Patent Application Publication No. 20140199555 entitled “Anticorrosion agents for transparent conductive film” (see e.g., abstract and claim 1).
[44] U.S. Patent Application Publication No. 20140170407 entitled “Anticorrosion agents for transparent conductive film” (see e.g., abstract and claim 1).
[45] U.S. Patent Application Publication No. 20140072826 entitled “Anticorrosion agents for transparent conductive film” (see e.g., abstract and claim 1).
[46] U.S. Patent Application Publication No. 20140170427 entitled “Anticorrosion agents for transparent conductive film” (see e.g., abstract and claim 1)
[47] U.S. Patent Application Publication No. 20110285019, entitled “Transparent conductors comprising metal nanowires,” (see e.g., claims 1, 7, 11, 12, 19).

### CONCLUSION

This concludes the description of the preferred embodiment of the present invention. The foregoing description of one or more embodiments of the invention has been presented for the purposes of illustration and description. It is not intended to be exhaustive or to limit the invention to the precise form disclosed. Many modifications and variations are possible in light of the above teaching. It is intended that the scope of the invention be limited not by this detailed description, but rather by the claims appended hereto.

1. An electrode structure, comprising:
a transparent conductive film having a first surface and a second surface, the second surface opposite the first surface; and
at least one first thermally stable material attached to the second surface, wherein:
the transparent conductive film includes a plurality of thermally stable nanowires and at least one polymer binder,
the thermally stable nanowires include metal nanowires,
the first surface includes conductive surfaces of a plurality of the nanowires,
the transparent conductive film has a sheet resistance that degrades by no more than 5% when heated to 250° C. for 1 hour, and
the transparent conductive film has a transmittance at a wavelength of 550 nm that decreases by no more than 5% when heated to 250° C. for 1 hour.

2. The structure of claim 1, wherein the metal nanowires comprise silver nanowires.

3. The structure of claim 1, wherein the metal nanowires consist essentially of metal.

4. The structure of claim 1, wherein the first surface has a surface roughness of 2 nanometers (nm) or less.

5. The structure of claim 1, wherein the first surface has a sheet resistance of 50 Ohms per square or less.

6. The structure of claim 1, wherein the metal nanowires are conformally coated with a second thermally stable material.

7. The structure of claim 1, wherein the thermally stable nanowires each comprise one of the metal nanowires and at least one overcoat protective layer deposited on the one of the metal nanowires by atomic layer deposition, the overcoat protective layer deposited with a thickness of 25 nm or less.

8. The structure of claim 7, wherein the least one polymer binder includes a layer of polyimide.

9. The structure of claim 7, wherein the at least one overcoat protective layer is at least one oxide selected from an oxide of zinc, an oxide of aluminum, an oxide of hafnium, an oxide of zirconium, and an oxide titanium.

10. The structure of claim 7, wherein the at least one overcoat protective layer is at least one nitride selected from a nitride of titanium, a nitride of tantalum, a nitride of hafnium, and a nitride of tungsten.

11. The structure of claim 7, wherein the at least one overcoat protective layer on the nanowires is formed from self-assembled monolayers.

12. The structure of claim 1, wherein the at least one first thermally stable material comprises a sheet of glass.

13. The structure of claim 12, wherein the sheet of glass is pre-coated with a layer of a difunctional compound having:
on one end a functional group that enables bonding to a glass surface of the sheet of glass, and
on the other end a functional group that enables bonding to the polymer binder.

14. The structure of claim 12, wherein the sheet of glass has a thickness in a range of 20-200 micrometers and the sheet of glass is flexible.

15. The structure of claim 13, wherein the difunctional compound comprises at least one compound selected from 3-(Monochlorosilyl)propyl methacrylate, 3-(Dichlorosilyl)propyl methacrylate, 3-(Trichlorosilyl)propyl methacrylate, 3-(Monoalkoxysilyl)propyl methacrylate, 3-(Dialkoxysilyl)propyl methacrylate, 3-(Trialkoxysilyl)propyl methacrylate, and polymers containing the same mono-/di-/tri-chloro silane and mono-/di-/tri-alkoxy silane but with styrl, acrylate, or other vinyl/olefin groups substituted for methacrylate.

16. The structure of claim 15, wherein the at least one polymer binder embedding the thermally stable nanowires comprises at least one polymer selected from polyimide, polyacrylate, polyurethane, silicone, epoxy, polybenzoxazole, polyhedral oligomeric silsequioxane, polydimethylsiloxane, and mixtures thereof.

17. The structure of claim 15 or 16, wherein the at least one polymer binder includes a layer of polyacrylate chemically bonded to the sheet of glass.

18. The structure of claim 15, wherein the at least one polymer binder contains light scattering particles.

19. The structure of claim 15, wherein the at least one polymer binder contains high refractive index nanoparticles with average diameter less than 10 nm.

20. (canceled)

21. (canceled)

22. (canceled)

23. A lighting panel comprising:
at least a light-emitting diode formed on the transparent conductive film on the thermally stable material of claim 1;
a solid barrier structure;
at least one seal for adhering said barrier structure to the thermally stable material, wherein:
the seal, the barrier structure, and the thermally stable material, in combination, define an enclosed space, and
the light emitting diode is within the enclosed space.

24. (canceled)

25. (canceled)

26. (canceled)

27. (canceled)

28. (canceled)

29. (canceled)

30. (canceled)

31. (canceled)

32. (canceled)

33. (canceled)

34. (canceled)

35. (canceled)

36. (canceled)

37. (canceled)

38. (canceled)

39. (canceled)

40. (canceled)

41. (canceled)

42. (canceled)

43. (canceled)

44. (canceled)

45. (canceled)

46. (canceled)

47. (canceled)

48. (canceled)

49. (canceled)
